(19) United States
(12) Patent Application Publication
(10) Pub. No.: US 2009/0257264 A1
(43) Pub. Date: Oct. 15, 2009

(54) MEMORY AND METHOD OF EVALUATING A MEMORY STATE OF A RESISTIVE MEMORY CELL

(76) Inventor: Heinz Hoenigschmid, Poecking (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 12/101,612

(22) Filed: Apr. 11, 2008

(51) Int. Cl. G11C 11/00; G11C 11/24

(52) U.S. Cl. 365/148; 365/149

(57) ABSTRACT

An integrated circuit comprises a first signal line, a second signal line and a resistive memory cell. The resistive memory cell is actively connectable to the first signal line. The integrated circuit further comprises a coupling device configured to generate a difference of potential between the first and second signal line when the resistive memory cell is actively connected to the first signal line.

### BACKGROUND OF THE INVENTION

In various data-processing systems and electronic devices so-called non-volatile memories are employed. These memories comprise programmable memory cells in which stored information can be reliably maintained even without external power supply. In this way, the memory content is not lost immediately upon switching off the supply voltage of the memory, contrary to so-called volatile memories such as DRAMs (dynamic random access memory).

### SUMMARY OF THE INVENTION

According to an embodiment, an integrated circuit comprises a first signal line, a second signal line and a resistive memory cell. The resistive memory cell may be actively connectable to the first signal line. The integrated circuit further comprises a coupling device configured to generate a difference of potential between the first and second signal line when the resistive memory cell is actively connected to the first signal line.

According to a further embodiment, a memory device comprises a plurality of signal lines and a plurality of resistive memory cells. Two directly adjacent signal lines each form a signal line pair. The resistive memory cells may be arranged at signal lines and may be actively connected to signal lines. The memory device further comprises a coupling device which capacitively influences an electric potential on a signal line of a signal line pair, at which signal line a resistive memory cell is arranged, in the course of activating the resistive memory cell for actively connecting the resistive memory cell to the signal line of the signal line pair in order to, starting from essentially corresponding electric potentials on the signal lines of the signal line pair, generate a difference of potential between the signal lines.

According to a further embodiment, a memory chip comprises a plurality of word lines, a plurality of bit lines and a plurality of resistive memory cells. Two directly adjacent bit lines each form a bit line pair. The resistive memory cells may be arranged at cross points of word lines and bit lines and may be actively connected to bit lines by activating word lines. Resistive memory cells arranged at a word line are each arranged at merely one of the two bit lines of the bit line pairs. The memory chip further comprises a coupling device which capacitively influences an electric potential on a bit line of a bit line pair, at which bit line a resistive memory cell is arranged, in the course of activating a word line associated with the resistive memory cell in order to, starting from essentially corresponding electric potentials on the bit lines of the bit line pair, generate a difference of potential between the bit lines of the bit line pair.

According to a further embodiment, a memory device comprises a plurality of signal lines and a plurality of resistive memory cells. Two directly adjacent signal lines each form a signal line pair. The resistive memory cells are arranged at signal lines and may be actively connected to signal lines. The memory device further comprises coupling means for capacitively influencing an electric potential on a signal line of a signal line pair, at which signal line a resistive memory cell is arranged, in the course of activating the resistive memory cell for actively connecting the resistive memory cell to the signal line of the signal line pair, and, starting from essentially corresponding electric potentials on the signal lines of the signal line pair, for generating a difference of potential between the signal lines of the signal line pair.

Another embodiment provides a method of evaluating a memory state of a resistive memory cell. The resistive memory cell is arranged at a first signal line. A second signal line is assigned to the first signal line. The method comprises the steps of: activating the resistive memory cell for actively connecting the resistive memory cell to the first signal line and capacitively influencing the electric potential on the first signal line in order to, starting from essentially corresponding electric potentials on the first and second signal line, generate a difference of potential between the first and second signal line, wherein, after actively connecting the resistive memory cell to the first signal line, the capacitively influenced electric potential on the first signal line is changed depending on the memory state of the resistive memory cell, and evaluating the memory state of the resistive memory cell by comparing the electric potentials on the first and second signal line.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic view of an integrated circuit comprising resistive memory cells according to an embodiment of the invention.

FIG. 2 illustrates a schematic view of an exemplary circuit arrangement of resistive memory cells, according to an embodiment of the invention.

FIGS. 3 and 4 illustrate schematic cross-sections of an upper side of a substrate of an exemplary CBRAM memory at different cross points of two word lines and a bit line, according to an embodiment of the invention.

FIGS. 5 and 6 illustrate schematic diagrams of exemplary electric potentials on word and bit lines during operation of the integrated circuit shown in FIG. 1, according to an embodiment of the invention.

FIG. 7 illustrates a schematic view of an alternative circuit arrangement of resistive memory cells, according to an embodiment of the invention.

FIG. 8 illustrates a schematic view of an exemplary computer system comprising a memory device, according to an embodiment of the invention.

FIG. 9 illustrates a schematic view of an exemplary computer system comprising a memory device, according to another embodiment of the invention.

FIG. 10 illustrates a schematic view of an exemplary integrated circuit comprising resistive memory cells, according to yet another embodiment of the invention.

FIG. 11 illustrates a schematic view of an exemplary integrated circuit comprising resistive memory cells, according to a further embodiment of the invention.

FIGS. 12 and 13 illustrate schematic diagrams of exemplary electric potentials on word and bit lines during operation of the integrated circuit shown in FIG. 11, according to an embodiment of the invention.

FIG. 14 illustrates a schematic view of an exemplary computer system comprising a memory device, according to yet another embodiment of the invention.

FIG. 15 illustrates a schematic view of an exemplary computer system comprising a memory device, according to another embodiment of the invention.

### DETAILED DESCRIPTION OF THE PREFERRED EMBODIMENT

Embodiments of the invention generally relate to evaluation of a memory state of a resistive memory cell. The resistive memory cell may be switched between two resistive states, which will in the following be called high resistive memory state and low resistive memory state. In these embodiments, prior to actively connecting a resistive memory cell to be read out to a signal line of a signal line pair, a relatively high difference of electric potential between the signal lines of the signal line pair may be evoked by means of capacitive influencing. After actively connecting the resistive memory cell to the respective signal line, the electric potential on the signal line may further change depending on the memory state of the resistive memory cell. On the basis of a subsequent comparison of the electric potentials on the signal lines of the signal line pair, the memory state of the resistive memory cell may be evaluated.

In the following, reference is made to embodiments of the invention. However, it should be understood that the invention is not limited to specific described embodiments. Instead, any combination of the following features and elements, whether related to different embodiments or not, is contemplated to implement and practice the invention. Furthermore, in various embodiments the invention provides numerous advantages over the prior art. However, although embodiments of the invention may achieve advantages over other possible solutions and/or over the prior art, whether or not a particular advantage is achieved by a given embodiment is not limiting of the invention. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Also, signal names used below are exemplary names, indicative of signals used to perform various functions in a given memory device. In some cases, the relative signals may vary from device to device. Furthermore, the circuits and devices described below and depicted in the figures are merely exemplary of embodiments of the invention. As recognized by those of ordinary skill in the art, embodiments of the invention may be utilized with any memory device.

Embodiments of the invention may generally be used with any type of memory. In one embodiment, the memory may be a circuit included on a device with other types of circuits. For example, the memory may be integrated into a processor device, memory controller device, or other type of integrated circuit device. Devices into which the memory is integrated may include system-on-a-chip (SOC) devices. In another embodiment, the memory may be provided as a memory device which is used with a separate memory controller device or processor device.

In both situations, where the memory is integrated into a device with other circuits and where the memory is provided as a separate device, the memory may be used as part of a larger computer system. The computer system may include a motherboard, central processor, memory controller, the memory, a hard drive, graphics processor, peripherals, and any other devices which may be found in a computer system. The computer system may be part of a personal computer, a server computer, or a smaller system such as an embedded system, personal digital assistant (PDA), or mobile phone.

In some cases, a device including the memory may be packaged together with other devices. Such packages may include any other types of devices, including other devices with the same type of memory, other devices with different types of memory, and/or other devices including processors and/or memory controllers. Also, in some cases, the memory may be included in a device mounted on a memory module. The memory module may include other devices including memories, a buffer chip device, and/or a controller chip device. The memory module may also be included in a larger system such as the systems described above.

In some cases, embodiments of the invention may be used with multiple types of memory or with a memory which is included on a device with multiple other types of memory. The memory types may include volatile memory and non-volatile memory. Volatile memories may include static random access memory (SRAM), pseudo-static random access memory (PSRAM), and dynamic random access memory (DRAM). DRAM types may include single data rate (SDR) DRAM, double data rate (DDR) DRAM, low power (LP) DDR DRAM, and any other types of DRAM. Nonvolatile memory types may include magnetic RAM (MRAM), flash memory, resistive RAM (RRAM), ferroelectric RAM (FeRAM), phase-change RAM (PRAM), electrically erasable programmable read-only memory (EEPROM), laser programmable fuses, electrically programmable fuses (e-fuses), and any other types of nonvolatile memory.

Non-volatile memories include data memories with resistive memory cells which comprise a resistive memory element. The memory state of a resistive memory cell may be defined by the electrical resistance of the resistive memory element and may be modified by applying electrical or magnetic signals. A binary coded memory cell may for example store a memory state “logical 0” in the form of a high resistive value and an opposite memory state “logical 1” in the form of a low resistive value.

A resistive type of memory is the so-called CBRAM memory (conductive bridging RAM) in which a memory cell comprises a resistive element having an electrolyte material arranged between two electrodes. The electrolyte material has a high specific resistance. By applying a programming voltage to the electrodes, a conductive path may be generated in the electrolyte material, thereby transferring the resistive element from a high resistive state to a low resistive state. This change of the resistive state may be reversed by applying a corresponding erase voltage. Detectable memory states of the CBRAM memory cell are defined by the different resistive values of the resistive element.

A further resistive memory is the phase change memory, also called PCRAM (phase change RAM). A PCRAM memory cell comprises a resistive element having a phase change material, typically a metal alloy, arranged between two electrodes. By applying electrical current pulses to the electrodes, the phase change material may be heated and thereby be switched between an amorphous and a crystalline phase state. Alternatively, the phase change material may be heated by means of a heating element. Depending on the phase state of the phase change material, the resistive memory cell is transferred into a high resistive memory state (amorphous phase) and into a low resistive memory state (crystalline phase), which is used for storing information.

Moreover, in other types of non-volatile resistive memories the generation of distinguishable resistive states of a memory cell is based on other electrical phenomena and properties. Examples therefore are e.g. memories based on transfer metal oxides.

Furthermore, MRAM memory (magneto-resistive RAM) may be considered which uses the properties of certain materials in order to change the electrical resistance under the influence of applied magnetic fields. A resistive element of an MRAM memory cell may for example comprise two magnetic layers which are separated from each other by means of a non-magnetic layer. Depending on the orientation of the magnetization of the magnetic layers with regard to each other, the electric resistance of the resistive element may be set.

In order to read out information from a resistive memory cell of a non-volatile memory, different read-out concepts may be used. A possible course of action is the application of a predetermined read voltage to the memory cell by means of a read-out circuit, in order to evoke a current flow through the memory cell depending on the resistive state of the memory cell. By detecting a current-depending measuring value, the memory state of the memory cell may be evaluated.

As an electrical measuring value, e.g. a voltage drop or a potential at a load element connected in series to the memory cell is measured. In order to evaluate the memory state of the memory cell, the measured potential may be compared to a predetermined reference potential. The reference potential is adjusted to the different memory states of the memory cell to be read out and reflects a mean resistive state between the memory states of the memory cell.

Generating of the reference potential may be carried out by means of two resistive memory cells connected in parallel and serving as reference. One of the reference cells is in a high resistive state, whereas the other reference cell is in a low resistive state. By applying the read voltage to the reference cells, reference currents are generated evoking the desired reference potential at two load elements connected in parallel. Alternatively, it is possible to generate the reference potential by means of a voltage source or a generator, respectively.

A further possible approach for reading out a resistive memory cell is to actively connect the memory cell to a signal line having a predetermined electric pre-charge potential and which is charged or discharged depending on the resistive state of the memory cell, respectively. In order to evaluate the memory state of the memory cell, the electric potential on the signal line may be compared to a reference potential after a predetermined period of time, the reference potential being adjusted to the different memory states of the memory cell.

The reference potential may be sensed at a reference line which is at first charged to the pre-charge potential and subsequently charged or discharged by actively connecting a reference cell. The reference cell thereby comprises a resistive value between the memory states of the memory cell to be read out. Alternatively, it is possible to generate the reference potential by means of an electric generator.

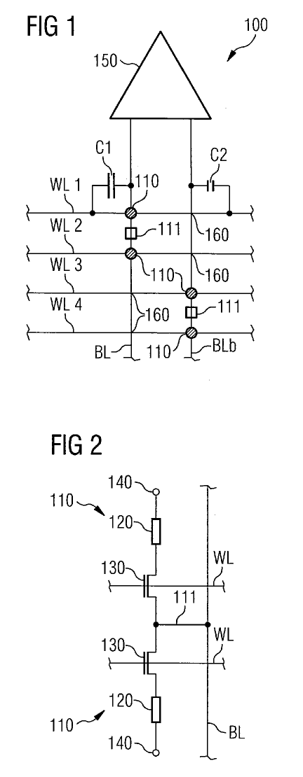

FIG. 1 is a schematic view of an integrated circuit 100 according to an embodiment of the invention. The integrated circuit 100 may include, e.g., four word lines WL and two bit lines BL, BLb, which may be arranged in rows and columns in the shape of a matrix, as illustrated in FIG. 1. In order to differentiate between the word lines, the word lines are denoted as WL1, WL2, WL3 and WL4. The bit lines BL, BLb form a bit line pair and may be connected to a sense amplifier 150.

The integrated circuit 100 further includes four memory cells 110, which are arranged at cross points of the word lines WL1, WL2 with the bit line BL, and at cross points of the word lines WL3, WL4 with the bit line BLb. Contrary thereto, no memory cells 110 may be provided at further cross points 160 of the word lines WL and the bit lines BL, BLb. In this manner, in one row a memory cell 110 is only arranged at one of the bit lines BL, BLb of the bit line pair, respectively. The two memory cells 110 arranged at the bit line BL as well as the two memory cells 110 arranged at the bit line BLb may have a joint bit line terminal 111 for contacting the bit lines BL, BLb.

A detailed view of a possible circuit arrangement of two resistive memory cells 110 with a joint bit line terminal 111 of the circuit 100 of FIG. 1 is shown in FIG. 2. A resistive memory cell 110 may include a programmable resistive element 120, the electrical resistance of which defines the memory state of the memory cell 110. The resistance of the resistive element 120 may be set by means of circuit elements not depicted in FIG. 2. Moreover, a resistive memory cell 110 may include a switch 130 which may be e.g. configured as a selection transistor 130.

A first terminal of the resistive element 120 of a memory cell 110 may be connected to a fixed reference potential 140, and a second terminal of the resistive element 120 may be connected to a first source/drain terminal of a selection transistor 130. A second source/drain terminal of the selection transistor 130 may be connected to the bit line terminal 111, and a gate of the selection transistor 130 may be connected to a word line WL. The bit line terminal 111 contacts a bit line BL or BLb, respectively.

In order to evaluate the memory state of a memory cell 110, the memory cell 110 may be activated in order to actively connect the memory cell 110 to the respective bit line BL. For this, the word line WL associated with the memory cell 110 may be activated, which comprises, apart from addressing the word line WL, the application of an activation potential to the addressed word line WL. In this way, the selection transistor 130 of the memory cell 110 arranged at the corresponding word line WL may be switched on and thereby the memory cell 110 may be actively connected to the associated bit line BL. Provided that the bit line BL comprises an electric potential differing from the reference potential 140, a current flow via the memory cell 110 may be evoked depending on the memory state of the memory cell 110, by means of which the bit line BL is charged or discharged.

In the integrated circuit 100 of FIG. 1, the differing capacitive coupling between a word line WL and the two bit lines BL, BLb of the bit line pair may be utilized to generate a difference of potential between the bit lines BL, BLb prior to actively connecting a memory cell 110 to one of the bit lines BL, BLb. In FIG. 1, this is depicted exemplarily for the word line WL1. At the cross point between the word line WL1 and the bit line BL, at which a memory cell 110 is arranged, a relatively large coupling capacitance C1 may occur. The coupling capacitance C1 may essentially be established by a coupling between the bit line terminal 111 and the word line WL1.

Contrary thereto, at the cross point 160 between the word line WL 1 and the complementary bit line BLb, a considerably smaller coupling capacitance C2 may occur. This may be due to the position of the bit line terminal 111 on the bit line BLb, and thus to a relatively larger distance between the word line WL1 and the bit line BLb. Corresponding coupling capacities of different strengths occur at the cross points between the further word lines WL2, WL3 and WL4 and the bit lines BL, BLb of the bit line pair.

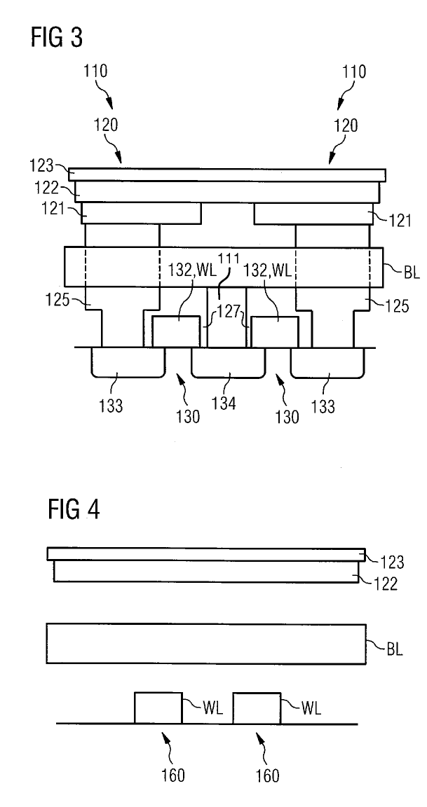

FIGS. 3 and 4 show schematic cross-sectional views of an upper side of a substrate of a CBRAM (Conductive Bridging RAM) memory at different cross points of two word lines WL and a bit line BL or BLb, respectively, in order to illustrate the occurrence of different coupling capacities. In the cross-sectional view of FIG. 3, two memory cells 110 having a programmable resistive element 120 and a selection transistor 130 are formed at the cross points. A resistive element 120 may include two electrodes 121, 123 and an electrolyte material 122, typically a chalcogenide material, arranged between the electrodes 121, 123. The electrode 123 as well as the electrolyte material 122 may be jointly utilized by the two memory cells 110.

The electrode 123 may include a conductive material such as silver, the ions of which penetrate the electrolyte material 122 upon application of a corresponding programming voltage to the electrodes 121, 123. In this manner, the ions in the electrolyte material 122 form a conductive path between the electrodes 121, 123, so that the electrical resistance of the resistive element 120 is small and the memory cell 110 comprises a low resistive memory state. By applying a corresponding erase voltage to the electrodes 121, 123, the ions may be repelled to the electrode 123. This dissolves the conductive path so that the resistance of the resistive element 120 becomes high and the memory cell 110 acquires a high resistive memory state. Instead of silver, the electrode 123 may comprise a different conductive material.

The electrodes 121 of the resistive elements 120 may be connected to doped, e.g. n+ doped areas 133 of the selection transistors 130 via connecting terminals 125. The selection transistors 130 moreover may include a further doped, e.g. n+ doped area 134 which may be jointly used by the two selection transistors 130. The areas 133, 134 thereby serve as source/drain terminals of the selection transistors 130. Moreover, the selection transistors 130 may include gates 132 connected to word lines WL or formed by word lines WL, respectively.

The source/drain terminal 134 may be connected to a bit line BL via a bit line terminal 111 associated with the two memory cells 110. By applying an activation potential to a word line WL or to a gate 132 of a selection transistor 130, respectively, a conductive channel may be formed between the source/drain terminals 133, 134, whereby the respective memory cell 110 is actively connected to the bit line BL. In this way, depending on the state of the memory cell 110, an electrical current may flow between the electrode 120, to which a fixed reference potential 140 is applied (see FIG. 2), and the bit line BL having a different potential.

Due to the bit line terminal 111 being arranged relatively close to a word line WL or to a gate 132, respectively, a relatively strong coupling capacitance C1 may result at a cross point of a word line WL and a bit line BL or BLb, respectively, at which the memory cell 110 is formed. At a cross point 160 of a word line WL and of a bit line BL or BLb, respectively, at which no memory cell 110 is provided, a relatively large distance between the word line WL and the bit line BL exists as can be seen from FIG. 4. The coupling capacitance C2 occurring at such a cross point 160 is consequently considerably smaller than the coupling capacitance C1 (see FIG. 1).

The difference between the coupling capacitances C1 and C2 may be so large that the coupling effect of the coupling capacitance C2 may be neglected in view of the coupling effect of the coupling capacitance C1. This may be achieved by a small distance between a bit line terminal 111 and a word line WL. For example, a distance smaller than 10 nm may be considered, e.g. in the range between 5 nm and 10 nm. Alternatively, other distances are conceivable. Moreover, an insulating material with a relatively high dielectric constant may be used for an insulation 127 provided between a bit line terminal 111 and a word line WL (see FIG. 3). This may include a high-k dielectric material, ferroelectric material, or the like. Alternatively, other materials may be used for the insulation 127. Corresponding approaches also apply memory cells other than the CBRAM memory cells 110 depicted in FIG. 3, such as PCRAM (Phase Change RAM) memory cells, MRAM memory cells and memory cells based on transitional metal oxides.

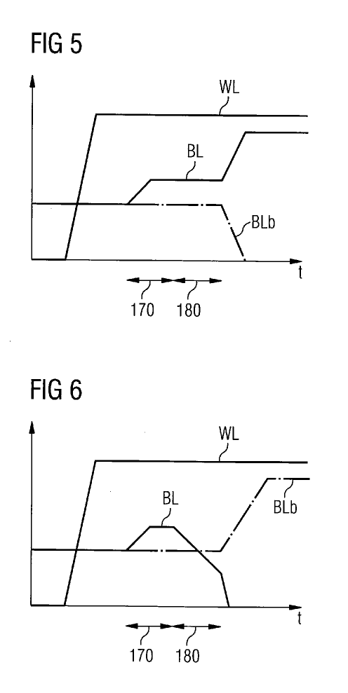

The following FIGS. 5 and 6 show schematic diagrams of electric potentials on a word line WL and on the bit lines BL, BLb of a bit line pair depending on the time t with regard to an exemplary operation mode of the integrated circuit 100 of FIG. 1 for evaluating the memory state of a resistive memory cell 110. FIG. 5 indicates the characteristics of electric potential for a high resistive memory state, and FIG. 6 indicates the characteristics of potential for a low resistive memory state of the memory cell 110 to be read out.

In the FIGS. 5 and 6, the designation WL refers to a potential characteristic of the word line WL1 or WL2, respectively, of FIG. 1, i.e. that a memory cell 110 is arranged at a cross point between the corresponding word line WL and the bit line BL, whereas no memory cell is arranged at a cross point 160 between a word line WL and the complementary bit line BLb. With regard to the word lines WL3 and WL4, analogue potential characteristics result wherein the designation BL and BLb for the potential characteristics of the bit lines are to be exchanged in FIGS. 5 and 6.

At first, the two bit lines BL, BLb of the bit line pair are charged to a common, e.g. positive pre-charge potential. In this way the bit lines BL, Blb have essentially corresponding electric potentials. This may be carried out by means of the sense amplifier 150 of the circuit 100. Alternatively, a pre-charge circuit may be used which is independent from the sense amplifier 150 and not depicted in FIG. 1. At this, the pre-charge potential is higher than the reference potential 140 applied at the memory cell 110 to be read out.

Subsequently, the word line WL is activated. Apart from addressing the word line WL, this process step comprises the application of e.g. a positive activation potential to the word line WL, whereby the potential on the word line WL increases as depicted in FIGS. 5 and 6 and acquires a constant value. The deviation of potential on the word line WL is e.g. 3V. Due to the coupling capacitance C1 between the word line WL and the bit line BL, the electric potential on the bit line BL is being pulled into a direction corresponding to the potential deviation of the word line WL. The effective period of this capacitive coupling is indicated in FIGS. 5 and 6 by means of an arrow 170. In one embodiment, the change of potential of the bit line BL is e.g. at least 50 mV. In alternative embodiments the change of potential may for example be in a range between 100 mV and 300 mV. Instead of the indicated values, the change of potential on the word line WL and on the bit line BL may have any other value.

As the coupling capacitance C2 between the word line WL and the complementary bit line BLb is considerably smaller than the coupling capacitance C1, the change of potential on the complementary bit line BLb is relatively small and may be negligible relative to the change of potential on the bit line BL. Therefore, the complementary bit line BLb still comprises essentially the pre-charge potential. In sum, the electric potential on the bit line BL may be increased compared to the electric potential on the complementary bit line BLb.

After a certain period of time, the application of the activation potential to the word line WL results in switching on the selection transistor 130 of the memory cell 110 and thus in actively connecting the memory cell 110 to the bit line BL. The further potential or signal development on the bit line BL, which in FIGS. 5 and 6 is shown by an arrow 180, may depend on whether the memory cell 110 is in the high resistive memory state or in the low resistive memory state.

In the high resistive memory state, in which the resistive element 120 of the memory cell 110 may have a high resistance value, no current or only a relatively small current may flow from the bit line BL via the memory cell 110 to the reference potential 140 (see FIG. 2). Therefore, essentially no or only a negligible change of potential on the bit line BL occurs, and the electric potential on the bit line BL may remain essentially constant, as shown in FIG. 5. Contrary thereto, in a low resistive memory state in which the resistive element 120 of the memory cell 110 may have a low resistance the electric potential on the bit line BL is pulled below the electric potential on the complementary bit line BLb, as shown in FIG. 6, since a discharge current may flow from the bit line BL via the memory cell 110 to the lower reference potential 140.

Subsequent to the signal development 180, for example, after waiting for a predetermined period of time, the electric potentials on the two bit lines BL, BLb of the bit line pair may be compared to each other. This may be carried out by means of the sense amplifier 150 which further amplifies the potential difference between the bit lines BL, BLb of the bit line pair. The higher bit line potential may hereby be pulled e.g. to a supply voltage and the lower bit line potential may be pulled to a mass potential. Alternatively, the bit line potentials may be pulled to other electric potentials.

The memory state of the resistive memory cell 110 may be evaluated using the amplified potential difference. Provided that the bit line BL is pulled to the higher potential, as shown in FIG. 5, it may be assumed that the memory cell 110 is switched into the high resistive memory state. In the reverse case, in which the complementary bit line BLb may be pulled to the higher potential as depicted in FIG. 6, it may be assumed that the memory cell 110 is switched into the low resistive memory state.

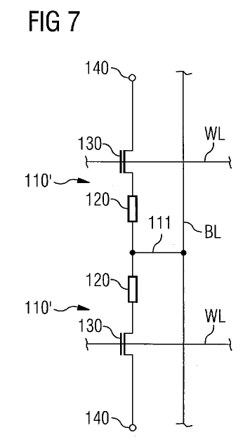

FIG. 7 shows a schematic view of an alternative circuit arrangement of two resistive memory cells 110′ having a joint bit line terminal 111, according to an embodiment of the invention. This circuit arrangement may be used in the integrated circuit 100 of FIG. 1. The differences between the circuit arrangement of FIG. 2 and FIG. 7 are represented by the different arrangement of a selection transistor 130 and of a resistive element 120 in a memory cell 110′. Specifically, the resistive element 120 is connected to the bit line terminal 111, and the selection transistor 130 is connected to a reference potential 140. The gate of the selection transistor 130 is connected to a word line WL. By activating a word line WL, the associated memory cell 110′ may be actively connected to a bit line BL or BLb, respectively, i.e. the bit line BL is charged or discharged via the memory cell 110′ depending on the memory state of the memory cell 110′, provided that the bit line potential differs from the reference potential 140.

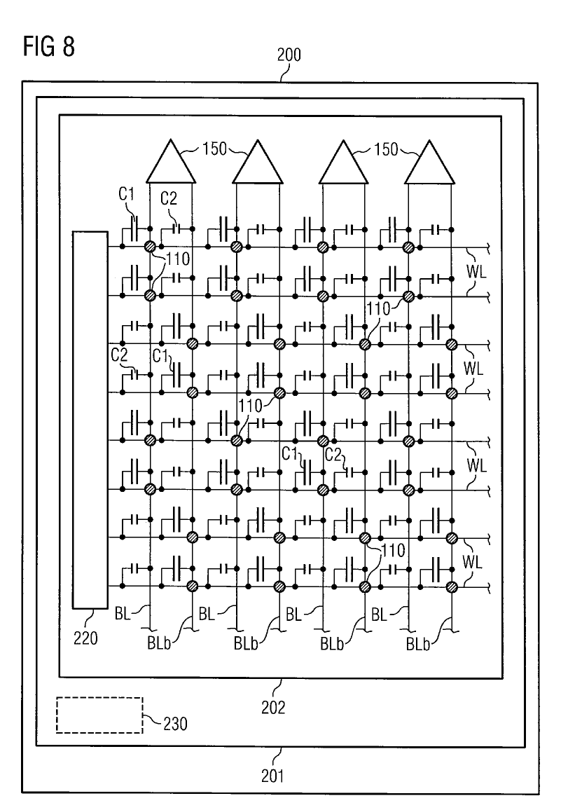

FIG. 8 shows a schematic view of a computer system 200 comprising a memory device 201 according to an embodiment of the invention. The memory device 201 may e.g. be a memory module which comprises a memory chip 202 or several memory chips 202. Alternatively, the memory device 201 may be a printed circuit board or a main board, respectively, which apart from the memory chip 202 or several memory chips 202 comprises further components such as a control unit 230 which is indicated in FIG. 8.

The memory chip 202 may have a layout corresponding to the integrated circuit 100 of FIG. 1 comprising a plurality of resistive memory cells 110 or 110′, respectively, which may be provided at cross points of a plurality of word lines WL and bit lines BL, BLb. The word lines WL and bit lines BL, BLb may be arranged in the form of rows and columns with regard to each other. Two directly adjacent bit lines BL, BLb may form one bit line pair each and may be connected to a sense amplifier 150. Moreover, the memory chip 202 may include an activation unit 220 connected to the word lines WL. An activation potential may be applied to a selected word line WL via the activation unit 220. In a column, two cross points may be alternately occupied and unoccupied by memory cells 110. In a row, the memory cells 110 may be merely arranged at one signal line BL or BLb of a signal line pair, respectively. Instead of the shown circuit layout, the memory chip 202 may include a different number of word lines WL and bit lines BL.

In the memory device 201 and in the memory chips 202, as well, the difference in the coupling capacities between the word lines WL and the bit lines BL, BLb of the bit line pairs may be utilized for evaluating the memory state of the memory cells 110. At the cross points between the word lines WL and the bit lines BL, BLb, at which memory cells 110 are arranged, a relatively large coupling capacitance C1 may occur due to the bit line terminals of the memory cells 110. At the other cross points at which no memory cells 110 are provided, a relatively small coupling capacitance C2 may occur which may be neglected compared to the capacity C1.

In the memory chip 202, memory cells 110 arranged in a row may be simultaneously read out by activating a word line WL. For this purpose, a row address referring to a word line WL may, for example, be transmitted from the control unit 230 to the activation unit 220, whereby the activation unit 220 applies an activation potential to the selected word line WL.

In this way, prior to actively connecting memory cells 110 of the respective row to the bit lines BL or BLb, the electric potentials may be essentially capacitively influenced on those bit lines BL or BLb of the bit line pairs, at the cross points to the respective word line WL of which resistive memory cells 110 are arranged. This may result in differences of potential between the bit lines BL, BLb of the bit line pairs which have previously been charged to a common pre-charge potential.

Upon actively connecting the resistive memory cells 110 of the selected row to the bit lines BL or BLb, respectively, the electric potentials on the bit lines BL or BLb, respectively, may be further changed depending on the memory state of the memory cells 110. The differences of potentials on the bit lines BL, BLb of the bit line pairs occurring after this signal development may be compared and amplified by the sense amplifiers 150. On the basis of the amplified differences of potential e.g. the control unit 230 may evaluate the memory states of the memory cells 110 of the selected row or word line WL, respectively.

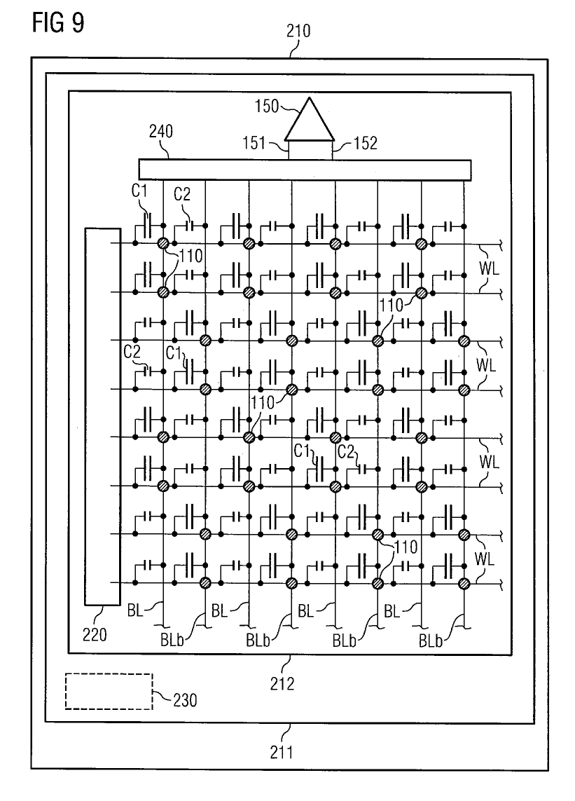

FIG. 9 shows a schematic view of a computer system 210 comprising a memory device 211 according to a further embodiment of the invention. The memory device 211 may be a memory module comprising one or several memory chips 212, or a printed circuit board or main board comprising one or several memory chips 212 and, as the case may be, further components such as a control unit 230.

The memory chip 212 generally comprises the same layout and the same functionality as the memory chip 202 depicted in FIG. 8. Contrary to the memory chip 202, a column selection unit 240 may be additionally provided in the memory component 212 of FIG. 9, by means of which bit lines BL, BLb of a bit line pair may be connected to a sense amplifier 150 via a first conductor 151 and a second conductor 152. In this way, the memory state of a memory cell 110 or 110′, respectively, arranged in a certain row or column may be evaluated upon a signal development on the bit lines BL, BLb of the associated bit line pair.

The memory chip 212 may comprise merely one single sense amplifier 150 and merely one single column selection unit 240 which is connected to all bit line pairs. Alternatively, the memory chip 212 may comprise several sense amplifiers 150 as well as several column selection units 240 connected to the sense amplifiers 150, wherein each column selection unit 240 is connected to a predetermined number of bit line pairs. Controlling of the column selection unit(s) 240 in order to connect the bit lines BL, BLb of a bit line pair to conductors 151, 152 of a sense amplifier 150 may be effected by means of the control unit 230. For this purpose, e.g. the control unit 230 may transfer a corresponding column address to a column selection unit 240.

Instead of generating a difference of potential on bit lines BL, BLb of a bit line pair by utilizing capacitive couplings between the bit lines BL, BLb and a word line WL, a capacitive circuit element may alternatively be used. In this way, there is a possibility of exerting a relatively large influence on the electric potential on one of the bit lines BL, BLb of the bit line pair prior to actively connecting a memory cell 110 to the respective bit line BL or BLb in order to cause a desired difference of potential between the bit lines BL, BLb.

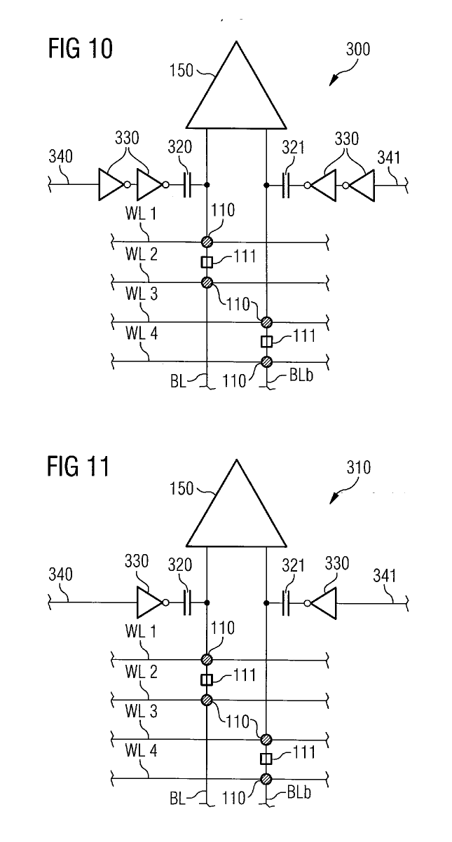

In this context, FIG. 10 depicts a schematic view of an integrated circuit 300 according to a further embodiment comprising resistive memory cells 110 or 110′, respectively. With regard to the arrangement of word lines WL, bit lines BL, BLb, memory cells 110 and a sense amplifier 150, the integrated circuit 300 corresponds to the circuit 100 indicated in FIG. 1.

Contrary to the circuit 100, the circuit 300 of FIG. 10 comprises additional capacitors 320, 321, which are in contact with the bit lines BL, BLb of the bit line pair via corresponding conductors. The capacitors 320, 321 are further connected to conductors 340, 341, by means of which an electric voltage may be applied to the capacitors 320, 321 in order to capacitively influence the electric potentials on the bit lines BL, BLb. Moreover, the circuit 300 comprises two inverters 330 in the conductor paths 340, 341 of the capacitors 320, 321. In this way, the influence of voltage oscillations on the capacitors 320, 321 may be reduced during application of a voltage.

During operation of the circuit 300 for evaluating the memory state of a memory cell 110, the capacitors 320, 321 may be used to influence the electric potential of that bit line BL or BLb of the bit line pair at which the respective memory cell 110 is arranged. For example, in the course of activating the word line WL1 or WL2, a voltage may be applied to the capacitor 320, and in the course of activating the word line WL3 or WL4, a voltage may be applied to the capacitor 321. Thereby, influencing the electric potentials on the bit lines BL, BLb due to capacitive couplings between a word line WL and the bit lines BL, BLb may be neglected.

With regard to a time development of the electric potentials on a word line WL and on the bit lines BL, BLb during operation of the circuit 300, reference may be made to the schematic characteristics of electric potential of FIGS. 5 and 6. In this context, the designation WL refers to a potential characteristic of the word lines WL1 or WL2, respectively, of FIG. 10. With regard to the word line WL3 and WL4, analogue potential characteristics result, wherein the designations BL and BLb for the potential characteristics of the bit lines are to be exchanged in FIGS. 5 and 6.

The bit lines BL, BLb of the bit line pair may be charged to a common pre-charge potential by means of the sense amplifier 150 or of a pre-charge circuit, the pre-charge potential being higher than the reference potential 140 applied at the memory cell 110 to be read out. An activation potential may be applied to the word line WL, which increases the potential on the word line WL as depicted in FIGS. 5 and 6 and may give it a constant value. In order to capacitively influence the bit line BL, a voltage may be applied to the capacitor 320, which draws the electric potential on the bit line BL into a direction corresponding to the potential deviation of the word line WL, and thus increases the electric potential on the bit line BL with regard to the electric potential on the complementary bit line BLb. In one embodiment, the potential deviation on the bit line BL is e.g. at least 50 mV. Alternatively, a potential deviation in the range between e.g. 100 mV and 300 mV may be considered. Instead of the indicated values, other values of potential are conceivable.

The FIGS. 5 and 6 depict the effective period 170 of the change of potential on the bit line BL evoked by means of the capacitor 320 after the change of potential on the word line WL. In one embodiment, the change of potential on the bit line BL, however, may also take place simultaneously to or prior to the change of potential on the word line WL, since the application of a voltage to the capacitor 320 may be carried out simultaneously to or prior to the application of an activation potential to the word line WL. The application of a voltage to the capacitor 320 may for example be induced by an addressing of the word line WL carried out in the course of activating the memory cell 110 to be read out.

After a certain period of time the application of the activation potential to the word line WL may result in switching on the selection transistor 130 of the memory cell 110 and therefore in actively connecting the memory cell 110 to the bit line BL. The further signal development 180 on the bit line BL depends, as described above, on the memory state of the memory cell 110. The difference in potential between the bit lines BL, BLb occurring after the signal development 180 may be compared and amplified by means of the sense amplifier 150 in order to evaluate the memory state of the memory cell 110.

Instead of charging the bit lines BL, BLb of a bit line pair to a pre-charge potential, which exceeds the reference potential 140 applied to a memory cell 110 or 110′, respectively, the bit lines BL, BLb may alternatively be brought to a pre-charge potential which is smaller than the reference potential 140. In such embodiments, capacitive influences may be used to reduce the electric potential on one of the bit lines BL or BLb of a bit line pair compared to the electric potential on the complementary bit line BLb or BL. This may, for example, be carried out by using a capacitor 320, 321 to pull the electric potential on the respective bit line BL or BLb into a direction opposite to the potential deviation on a word line WL.

In this context, FIG. 11 depicts a schematic view of an integrated circuit 310 according to a further embodiment. The circuit 310 essentially comprises the same layout as the circuit 300 of FIG. 10. Contrary to the circuit 300, the circuit 310 of FIG. 11 comprises merely one inverter 330 in the conductor paths 340, 341 of the capacitors 320, 321. In this way, a voltage applied to the capacitors 320, 321 may be inverted and thus the electric potential on the bit lines BL, BLb of the bit line pair may be pulled in a direction opposite to the potential deviation of a word line WL.

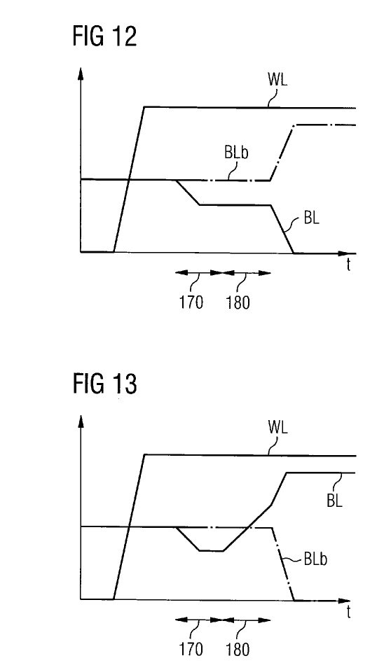

In the following FIGS. 12 and 13, time characteristics of electric potentials on a word line WL and the bit lines BL, BLb of a bit line pair are schematically shown for an exemplary operation mode of the integrated circuit 310 of FIG. 11 in order to evaluate the memory state of a resistive memory cell 110 or 110′, respectively. FIG. 12 indicates the potential characteristics for a high resistive memory state, and FIG. 13 for a low resistive memory state of the memory cell 110 to be read out.

In FIGS. 12 and 13, the designation WL refers to a potential characteristic of the word line WL1 or WL2, respectively, of FIG. 11, at the cross point with the bit line BL of which a memory cell 110 is arranged. With regard to the word lines WL3 and WL4, corresponding potential characteristics result, wherein the designations BL and BLb for the potential characteristics of the bit lines are to be exchanged in FIGS. 12 and 13.

The bit lines BL, BLb of the bit line pair may be first charged to a common pre-charge potential by means of the sense amplifier 150 or a pre-charge circuit, the pre-charge potential being smaller than the reference potential 140 applied to the memory cell 110 to be read out. An activation potential may be applied to the word line WL, whereby the potential on the word line WL increases as depicted in FIGS. 12 and 13 and acquires a constant value. In order to capacitively influence the bit line BL, an inverted voltage may be applied to the capacitor 320, whereby the electric potential on the bit line BL is drawn in a direction contrary to the potential deviation of the word line WL and the electric potential on the bit line BL is reduced compared to the electric potential of the complementary bit line BLb. In one embodiment, the change of potential on the bit line BL is e.g. at least 50 mV. In alternative embodiments, the change in potential may be e.g. between 100 mV and 300 mV. Alternatively, other values are also conceivable.

FIGS. 12 and 13 depict the effective period 170 of the change of potential on the bit line BL caused by means of the capacitor 320 after the change of potential on the word line WL. The change of potential on the bit line BL, however, may also take place simultaneously to or prior to the change of potential on the word line WL, since the application of a voltage to the capacitor 320 may already be initiated e.g. by means of an addressing of the word line WL carried out in the course of activating the word line WL.

After a certain period of time, the application of the activation potential to the word line WL may result in switching on the selection transistor 130 of the memory cell 110 and thus in actively connecting the memory cell 110 to the bit line BL. The further potential and signal development 180 on the bit line BL depends on the memory state of the memory cell 110.

In the high resistive memory state of the memory cell 110 no or only a relatively low current flows from the reference potential 140 to the bit line BL via the memory cell 110. The potential on the bit line BL thus remains essentially constant, as depicted in FIG. 12. In contrast thereto, in a low resistive state of the memory cell 110 the electric potential on the bit line BL is raised over the electric potential on the complementary bit line BLb, as shown in FIG. 13, as a charge current may flow from the reference potential 140 to the bit line BL.

Subsequent to the signal development 180, e.g. after waiting for a predetermined period of time, the electric potentials on both bit lines BL, BLb of the bit line pair may be compared by means of the sense amplifier 150 and a difference of potential between the bit lines BL, BLb may be amplified. The memory state of the memory cell 110 may be evaluated by means of the amplified potential difference. In case the complementary bit line BLb is drawn to the higher bit line potential, as depicted in FIG. 12, it may be assumed that the resistive memory cell 110 is switched into the high resistive memory state. Provided that the bit line BL is drawn to the higher potential, as shown in FIG. 13, it may be assumed that the resistive memory cell 110 is switched into the low resistive memory state.

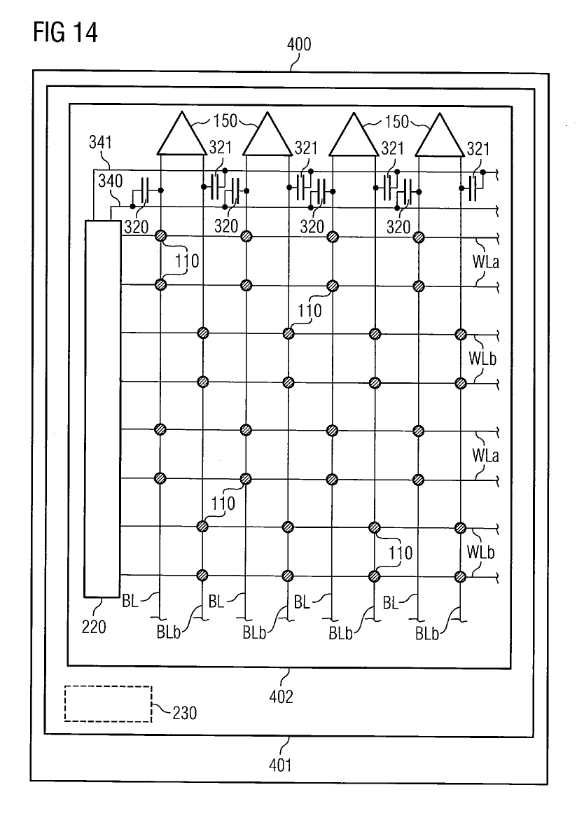

FIG. 14 depicts a schematic view of a computer system 400 comprising a memory device 401. The memory device 401 may e.g. be a memory module which comprises a memory chip 402 or several memory chips 402. Alternatively, the memory device 401 may be a printed circuit board or a main board, respectively, which apart from the memory chip 402 or several memory chips 402 comprises further components such as a control unit 230 which is indicated in FIG. 14.

The memory chip 402 may have a layout corresponding to the integrated circuit 300 or 310, respectively, of FIGS. 10 and 11, comprising a plurality of resistive memory cells 110 or 110′, respectively, which are provided at cross points of a plurality of word lines WL and bit lines BL, BLb. For reasons of differentiation, the word lines are in this context designated as Wla and WLb. Furthermore, the memory chip 402 includes an activation unit 220 connected to the word lines WL, by means of which an activation potential may be applied to a selected word line WL. Addressing of the activation unit 220 may be carried out by means of the control unit 230. Instead of the depicted circuit layout, the memory chip 402 may comprise a different number of word lines WL and bit lines BL.

Two directly adjacent bit lines BL, BLb form one bit line pair each and may be connected to a sense amplifier 150. Additionally, the bit lines BL, BLb may be connected to capacitors 320 and 321, by means of which the bit lines BL, BLb may be capacitively influenced. For this purpose, the capacitors 320, 321 are further connected to the activation unit 220 via conductors 340, 341, the activation unit 220 serving as a voltage source for applying a voltage to the capacitors 320, 321. In the course of activating the word lines WLa, a voltage may be applied to the conductor 340 and thus to the capacitors 320, and in the course of activating the word lines WLb, to the conductor 341 and thus to the capacitors 321. In this way, the potential may be capacitively influenced on that bit line BL or BLb of a bit line pair, at the cross point with the respective word line WL of which a memory cell 110 is arranged. Inverters (not depicted) which may be provided in the conductor paths 340, 341 may be integrated in the activation unit 220.

In the memory chip 402, memory cells 110 arranged in one row may be simultaneously read out by activating a word line WL. For this purpose, a row address referring to a word line WL may e.g. be transferred from the control unit 230 to the activation unit 220, which causes the activation unit 220 to apply an activation potential to the selected word line WL. Furthermore, the activation unit 220 may apply a voltage to one of the conductors 340 or 341 on the basis of the row address in order to capacitively influence one of the bit lines BL or BLb of all bit line pairs prior to actively connecting memory cells 110 to the bit lines BL or BLb. Thus, differences of potential are evoked between the bit lines BL, BLb of the bit line pairs which have previously been charged to a common pre-charge potential.

After actively connecting memory cells 110 to the bit lines BL or BLb, the electric potentials on the bit lines BL or BLb may further change depending on the memory state of the memory cells 110. The differences of potential on the bit lines BL, BLb occurring after this signal development may be compared and amplified by means of the sense amplifiers 150. On the basis of the amplified differences of potential e.g. the control unit 230 may carry out an evaluation of the memory states of the memory cells 110 of the selected row.

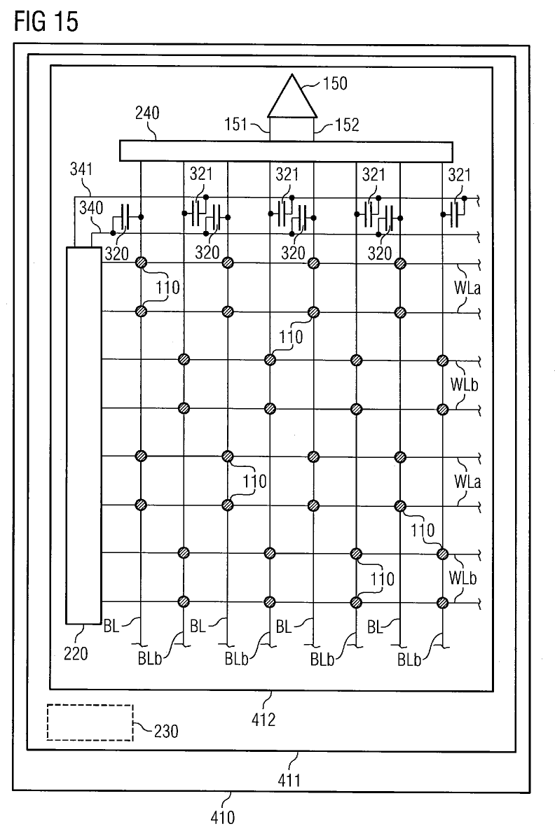

FIG. 15 shows a schematic view of a computer system 410 comprising a memory device 411 according to a further embodiment of the invention. The memory device 411 may also be a memory module with one or several memory chips 412 as well as a printed circuit board or a main board comprising one or several memory chips 412 as well as further components such as a control unit 230.

The memory chip 412 essentially comprises the same layout and the same functionality as the memory chip 402 depicted in FIG. 14. In contrast to the memory chip 402, a column selection unit 240 is additionally provided in the memory chip 412 of FIG. 15, by means of which bit lines BL, BLb of a bit line pair may be connected to a sense amplifier 150 via a first conductor 151 and a second conductor 152. In this way, the memory state of a memory cell 110 or 110′ arranged in a certain row and column may be evaluated.

The memory chip 412 may comprise merely one single sense amplifier 150 and merely one single column selection unit 240 connected to all bit line pairs. Alternatively, the memory chip 412 may comprise several sense amplifiers 150 as well as several column selection units 240 connected to the sense amplifiers 150, each column selection unit 240 being connected to a predetermined number of bit line pairs, respectively. Controlling of the column selection unit(s) 240 in order to connect the bit lines BL, BLb of a bit line pair to conductors 151, 152 of a sense amplifier 150 may be carried out by means of the control unit 230 by transmitting a corresponding column address.

The embodiments described in conjunction with the drawings are exemplary embodiments. Moreover, further embodiments may be realized which comprise modifications.

For instance, instead of an activation unit 220, which is simultaneously employed for activating word lines WL and applying a voltage to a capacitor 320, 321, a voltage source which is separate from the activation unit 220 may be provided for applying a voltage to a capacitor 320, 321.

Furthermore, it is possible to use resistive memory cells in an integrated circuit and in a memory device, each having their own bit line terminal. Thereby, the memory cells may e.g. be arranged at word lines and bit lines organized in the form of rows and columns in such a way that in a row as well as in a column a cross point is alternately occupied and unoccupied by a memory cell.

Furthermore, a negative activation potential may be applied to a word line instead of a positive activation potential. In this regard, too, a potential on a bit line may be drawn in a direction corresponding to as well as contrary to the deviation of potential of the word line by means of capacitive influencing.

Furthermore, embodiments may be realized comprising resistive memory cells, wherein a resistive memory cell comprises, unlike a selection transistor or a switch, a different component like e.g. a diode. A diode may also be utilized for the purpose of selectively activating a memory cell and thus for actively connecting a memory cell to a corresponding bit line or signal line, respectively. Correspondingly, such embodiments may comprise capacitively influencing the electric potential on a signal line in the course of activating a respective memory cell, wherein capacitively influencing may be effected e.g. by means of a capacitor connected to the respective signal line.

The embodiments may be used with respect to any kind of resistive memory concept. In this regard, e.g. CBRAMs, PCRAMs, MRAMs and memories on the basis of transitional metal oxides may be considered.

The preceding description describes exemplary embodiments of the invention. The features disclosed therein and the claims and the drawings can, therefore, be useful for realizing the invention in its various embodiments, both individually and in any combination. While the foregoing is directed to embodiments of the invention, other and further embodiments of this invention may be devised without departing from the basic scope of the invention, the scope of the present invention being determined by the claims that follow.

What is claimed is:

1. An integrated circuit, comprising:
a first signal line;
a second signal line;
a resistive memory cell configured to be actively connected to the first signal line; and
a coupling device configured to generate a difference of potential between the first and second signal line when the resistive memory cell is actively connected to the first signal line.

2. The integrated circuit according to claim 1, further comprising a control line, wherein the resistive memory cell is arranged at a cross point of the control line and the first signal line, and wherein the switching device is configured to couple the resistive memory cell with the first signal line when the control line is activated.

3. The integrated circuit according to claim 2, wherein the resistive memory cell comprises a signal line terminal connected to the first signal line, and wherein the coupling device is a capacitive structure comprising the control line, the signal line terminal, and an insulating material arranged between the control line and the signal line terminal.

4. The integrated circuit according to claim 3, wherein a distance between the signal line terminal and the control line is in a range between 10 nm and 5 nm.

5. The integrated circuit according to claim 3, wherein the insulating material is one of a high-k dielectric and a ferroelectric material.

6. The integrated circuit according to claim 1, wherein the coupling device comprises a capacitor.

7. The integrated circuit according to claim 6, wherein the capacitor is connected to the first signal line, and wherein the coupling device further comprises a voltage source which applies a voltage to the capacitor for capacitively influencing the electric potential on the first signal line to generate the difference of potential between the first and second signal line.

8. The integrated circuit according to claim 6, wherein the coupling device comprises at least one inverter.

9. The integrated circuit according to claim 1, further comprising an evaluation device connected to the first and second signal line for comparing the electric potentials on the first and second signal line.

10. The integrated circuit according to claim 1, wherein the resistive memory cell comprises a resistive memory element.

11. The integrated circuit according to claim 1, wherein the difference of potential between the first and second signal line generated by the coupling device is at least 50 mV.

12. A memory device, comprising:
a plurality of signal lines, wherein two directly adjacent signal lines each form a signal line pair;
a plurality of resistive memory cells which are arranged at the signal lines and which are configured to be actively connected to respective signal lines; and
a coupling device configured to alter an electric potential on a first signal line of a signal line pair, wherein a resistive memory cell is arranged at the first signal line, the altering of the electric potential being performed in the course of activating the resistive memory cell for actively connecting the resistive memory cell to the first signal line of the signal line pair in order to, starting from corresponding electric potentials on the signal lines of the signal line pair, generate a difference of potential between the signal lines.

13. The memory device according to claim 12, further comprising a plurality of control lines, wherein resistive memory cells are arranged at cross points of control lines and respective signal lines, wherein the resistive memory cells comprise signal line terminals connected to respective signal lines, and wherein the coupling device is a capacitive structure comprising the control line, the signal line terminal, and an insulating material arranged between the control line and the signal line terminal.

14. The memory device according to claim 13, wherein two resistive memory cells each comprise a joint signal line terminal.

15. The memory device according to claim 12, wherein the coupling device comprises capacitors connected to the signal lines and a voltage source which applies a voltage to a capacitor for capacitively influencing the electric potential on a signal line.

16. A memory chip, comprising:
a plurality of word lines;
a plurality of bit lines, wherein two directly adjacent bit lines each form a bit line pair;
a plurality of resistive memory cells which are arranged at cross points of word lines and bit lines and which are configured to be actively connected to respective bit lines by activating respective word lines, wherein resistive memory cells arranged at a word line are each arranged at one of the two bit lines of the bit line pairs; and
a coupling device configured to capacitively alter an electric potential on a bit line of a bit line pair at which a resistive memory cell is arranged in the course of activating a word line associated with the resistive memory cell in order to, starting from corresponding electric potentials on the bit lines of the bit line pair, generate a difference of potential between the bit lines of the bit line pair.

17. A memory device, comprising:
a plurality of signal lines, wherein two directly adjacent signal lines each form a signal line pair;
a plurality of resistive memory cells which are arranged at the signal lines and configured to be actively connected to respective signal lines; and
coupling means configured to capacitively alter an electric potential on a first signal line of a signal line pair, a resistive memory cell being arranged at the first signal line, in the course of activating the resistive memory cell for actively connecting the resistive memory cell to the first signal line of the signal line pair and, starting from essentially corresponding electric potentials on the signal lines of the signal line pair, for generating a difference of potential between the signal lines of the signal line pair.

18. A method of evaluating a memory state of a resistive memory cell, wherein the resistive memory cell is arranged at a first signal line of a signal line pair, comprising the steps of:
activating the resistive memory cell for actively connecting the resistive memory cell to the first signal line;
capacitively influencing the electric potential on the first signal line in order to, starting from essentially corresponding electric potentials on the first and second signal line, generate a difference of potential between the first and second signal line, wherein, after actively connecting the resistive memory cell to the first signal line, the capacitively influenced electric potential on the first signal line is changed based on the memory state of the resistive memory cell; and
evaluating the memory state of the resistive memory cell by comparing the electric potentials on the first and second signal line.

19. The method according to claim 18, wherein the first signal line is connected to a capacitor, and wherein capacitively influencing the electric potential on the first signal line is carried out by applying a voltage to the capacitor.

20. The method according to claim 18, wherein the resistive memory cell is arranged at a cross point of the first signal line and a control line, wherein activating the resistive memory cell for actively connecting the resistive memory resistive memory cell comprises a signal line terminal connected to the first signal line, and wherein capacitively influencing the electric potential on the first signal line is based on a capacitive coupling between the signal line terminal and the control line.

21. The method according to claim 18, wherein capacitively influencing the electric potential on the first signal line causes the electric potential on the first signal line to be increased compared to the electric potential on the second signal line.

22. The method according to claim 21, wherein the resistive memory cell is configured to be switched from a high resistive memory state to a low resistive memory state, and wherein, in case of the resistive memory cell being switched into the low resistive memory state, the electric potential on the first signal line is pulled below the electric potential on the second signal line after actively connecting the resistive memory cell to the first signal line.

23. The method according to claim 18, wherein capacitively influencing the electric potential on the first signal line causes the electric potential on the first signal line to be decreased compared to the electric potential on the second signal line.

24. The method according to claim 23, wherein the resistive memory cell is configured to be switched from a high resistive memory state to a low resistive memory state, and wherein, in case of the resistive memory cell being switched into the low resistive memory state, the electric potential on the first signal line is raised over the electric potential on the second signal line after actively connecting the resistive memory cell to the first signal line.

25. The method according to claim 18, wherein the first signal line and the second signal line are charged to a common pre-charge potential before activating the resistive memory cell.
